(19) United States
(12) Patent Application Publication
(10) Pub. No.: US 2007/0267711 A1
(43) Pub. Date: Nov. 22, 2007

(54) OPTICAL RECEIVING DEVICE

(76) Inventors: Kazushige Yamamoto, Yokohama-shi (JP); Tatsuo Shimizu, Tokyo (JP); Shigeru Haneda, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/688,595

(22) Filed: Mar. 20, 2007

(30) Foreign Application Priority Data
May 17, 2006 (JP) 2006-138023

(51) Int. Cl. H01L 31/0232

(52) U.S. Cl. 257/432; 257/E31.127

(57) ABSTRACT

An optical receiving device has a photoelectric conversion layer including a matrix semiconductor containing silicon atoms as a main component, an n-type dopant D substituted for the silicon atom in a lattice site, and a heteroatom Z inserted into an interstitial site positioned closest to the n-type dopant D, in which the heteroatom Z has an electron configuration of a closed shell structure through charge compensation with the dopant D.

### CROSS-REFERENCE TO RELATED APPLICATIONS

This application is based upon and claims the benefit of priority from prior Japanese Patent Application No. 2006-138023, filed May 17, 2006, the entire contents of which are incorporated herein by reference.

### BACKGROUND OF THE INVENTION

1. Field of the Invention

The present invention relates to optical receiving devices based on a filled tetrahedral (FT) semiconductor.

2. Description of the Related Art

Silicon optical receiving devices are not only used in photo detectors as unit elements but also widely applied to integrated devices such as CCD image sensors, COMS image sensors, and solar cells.

Unfortunately, it is very difficult for silicon optical receiving devices to provide both high sensitivity (quantum efficiency) and high response speed compared to optical receiving devices comprising germanium with a narrow-gap or GaAs, which is a direct semiconductor (see S. M. Sze, Physics of Semiconductor Devices, Chapter 13, pp. 754-760 (John Wiley & Sons, 2nd ed.).

A comparison of silicon with germanium and GaAs with respect to their absorption spectra indicates that silicon exhibits an absorption coefficient at least one order of magnitude lower than those of germanium and GaAs from a near-infrared region to a visible region in the vicinity of the band edge. Further, for the silicon optical receiving device, it is known that there is a trade-off between two light receiving characteristics of sensitivity and response speed owing to the low absorption coefficient of silicon. That is, increasing the thickness of a photocarrier generation layer increases the amount of incident light absorbed to improve the sensitivity. However, at the same time, the traveling distance of carriers increases to reduce the response speed. In contrast, reducing the thickness of the photocarrier generation layer improves the response speed but lowers the sensitivity.

Thus, the small absorption coefficient of silicon is a direct cause of the trade-off between high sensitivity and fast response in the silicon optical receiving device. A more essential cause is the fact that silicon is an indirect semiconductor with a wide band gap unlike germanium or GaAs. Accordingly, it is difficult to solve the above problem as long as silicon is used for the photocarrier generation layer.

As described above, it is disadvantageously difficult for the silicon optical receiving device to provide both high sensitivity and fast response. The direct cause is the low absorption coefficient of silicon, and the more essential cause is the fact that silicon is an indirect semiconductor.

### BRIEF SUMMARY OF THE INVENTION

According to an aspect of the present invention, there is provided an optical receiving device, comprising: a photoelectric conversion layer comprising a matrix semiconductor containing silicon atoms as a main component, an n-type dopant D substituted for the silicon atom in a lattice site, and a heteroatom Z inserted into an interstitial site positioned closest to the n-type dopant D, the heteroatom Z having an electron configuration of a closed shell structure through charge compensation with the dopant D.

According to another aspect of the present invention, there is provided an optical receiving device, comprising: a photoelectric conversion layer comprising a matrix semiconductor containing silicon atoms as a main component, a p-type dopant A substituted for the silicon atom in a lattice site, and a heteroatom Z inserted into an interstitial site positioned closest to the p-type dopant A, the heteroatom Z having an electron configuration of a closed shell structure through charge compensation with the dopant A.

### BRIEF DESCRIPTION OF THE SEVERAL VIEWS OF THE DRAWING

FIG. 1 is a band diagram showing change in the band structure of silicon having isotropic stretching applied thereto;

FIGS. 2A and 2B show band diagrams of crystalline silicon and He-doped FT-silicon, respectively;

FIG. 3 is a spectrum illustrating change in absorption coefficient of silicon into which an FT structure is introduced;

FIGS. 4A, 4B, and 4C are diagrams illustrating electron states in the real space in respect of the Γ point conduction band, the X point conduction band and the Γ point valence band of the energy bands of silicon;

FIG. 5 is an energy band diagram of silicon illustrating the reason why an FT semiconductor more significantly absorbs light;

FIG. 6 is a diagram showing the structure of a pendant type FT semiconductor;

FIGS. 7A and 7B show band diagrams of silicon having a PF pair concentration of zero and a pendant type FT-Si having a PF pair concentration of 6.3×10²¹/cm³, respectively;

FIGS. 8A and 8B are cross-sectional views showing the structures of silicon optical receiving devices of a vertical type and a lateral type, respectively, according to embodiments;

FIGS. 9A, 9B, 9C and 9D are cross-sectional views showing a method of forming a photocarrier generation layer (photoelectric conversion layer) of a PF-doped FT-Si according to an embodiment;

FIG. 10 is a graph showing response characteristics to input signals of the optical receiving device according to a first embodiment;

FIG. 11 is a graph showing response characteristics to input signals of the optical receiving device according to a second embodiment;

FIGS. 12A and 12B are a cross-sectional view and a circuit diagram, respectively, of the CMOS image sensor according to a third embodiment;

FIG. 13 is a cross-sectional view of the CCD image sensor according to a fourth embodiment; and

FIGS. 14A and 14B are a plan view and a cross-sectional view, respectively, of the solar cell according to a fifth embodiment.

### DETAILED DESCRIPTION OF THE INVENTION

Embodiments of the present invention use a filled tetrahedral (FT) semiconductor as a band engineering method of modulating the band structure of a semiconductor. The term “FT semiconductor” conventionally refers to a crystalline solid in which a rare gas atom or a diatomic molecule with an electron configuration of a closed shell is introduced into an “interstitial site” of a matrix semiconductor having a tetrahedral structure such as a diamond structure or a zinc blende structure. The effects of the FT semiconductor, the core of the present invention, will be described in detail.

Described in the first step are (1) the reason why an indirect semiconductor such as silicon has an indirect band structure, and (2) the reason why the indirect semiconductor has a low absorption coefficient. Then described are (3) the feature of the FT semiconductor (rare gas-containing FT semiconductor and molecule-containing FT semiconductor), and (4) the principle of enhanced absorption. Further described is (5) a novel FT semiconductor, i.e., a pendant type FT semiconductor, which constitutes the important part of the present invention.

(1) Band Structure of the Indirect Semiconductor:

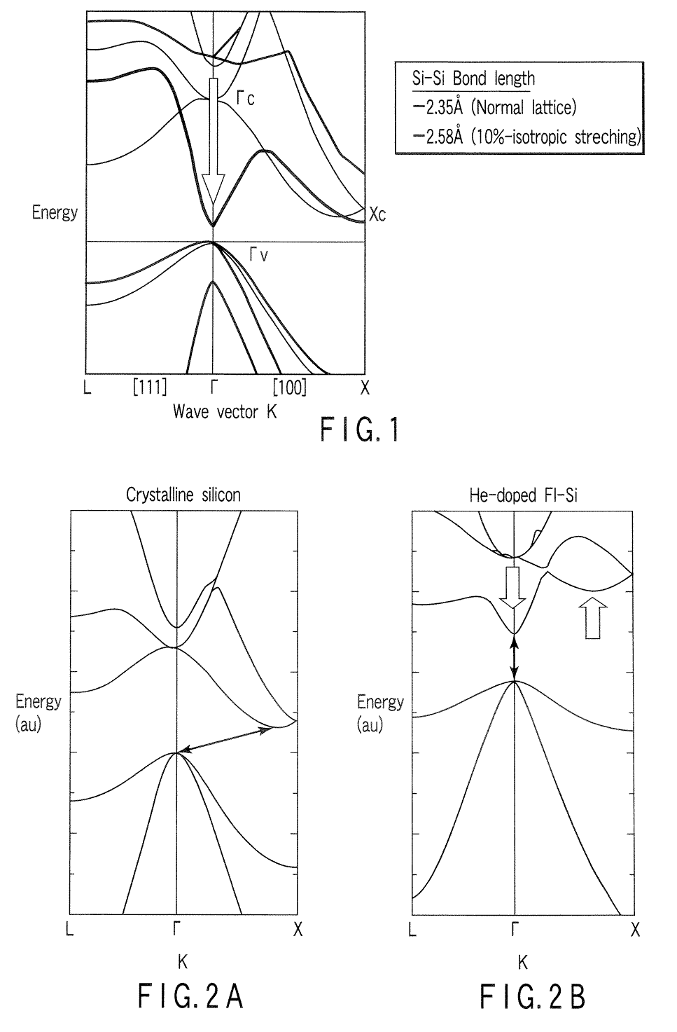

FIG. 1 shows the band structure of silicon. Originally, the main reason why silicon forms an indirect semiconductor resides in that the bond length d between the adjacent Si atoms is relatively short. The energy difference ΔE between the conduction band and the valence band at the Γ point is a function of the bond length d and can be represented approximately by ΔE∝1/d². Therefore, the energy difference ΔE is rapidly diminished with increase in the bond length d and is changed to be adapted to a direct band structure.

FIG. 1 shows, together with the band structure of a normal lattice, the result of the calculation of the band structure of an imaginary lattice, covering the case where the lattice is stretched through a strain effect in the direction of the crystal axis <111> so as to increase the Si—Si bond length by 10%. In the drawing, the band structures of the normal lattice and of the imaginary lattice are depicted to permit the upper edges of the valence bands to be matched.

As shown in FIG. 1, if the bond length is increased, the conduction band is markedly dropped at the Γ point, though a marked change is not observed in the X point, so as to be changed into a direct band structure resembling that of GaAs. Roughly speaking, the energy difference ΔE is diminished because the bond is elongated so as to decrease the repulsion energy between electrons, with the result that the conduction band (s-orbital) positioned upward in the normal lattice is lowered to approach the valence band (p-orbital). However, it is likely to be difficult to increase the bond length by the order of 10%.

(2) Optical Characteristics of an Indirect Semiconductor:

In the indirect semiconductor, the electric dipole transition is optically forbidden. Thus, the indirect semiconductor exhibits only weak absorption attributed to a phonon-assisted indirect transition in a low energy region near the band edge (i.e., it has a low absorption coefficient). In contrast to the above, a direct transition attributed to an electric dipole transition occurs in a direct semiconductor such as GaAs, leading to significant absorption (i.e., it has a high absorption coefficient). The difference between the two semiconductors is mainly caused by whether the two selection rules given below are satisfied.

One of the selection rules relates to the wave number, i.e., the requirement that the energy gap should be made smallest at the specified wave number. The other selection rule relates to symmetry of the wave function, i.e., the requirement that, in the wave number that makes the gap minimum, one of the conduction band and the valence band should be an even function and the other should be an odd function.

It should be noted in respect of the selection rule of the symmetry that the intensity of the emission and the absorption between two levels is given by <upper level|transition dipole moment μ|lower level>. For a semiconductor in which the two levels are represented by an s-orbital (even function) and a p-orbital (odd function) in the vicinity of an atomic orbital, μ corresponds to an odd function, so that the following relation is met, which means that this semiconductor is optically allowed.

<s|μ|p>=∫even·odd·odd dr≠0.

On the other hand, for a semiconductor in which the two levels are represented by the p-orbital, the following relation is met, which means that this semiconductor is optically forbidden:

<p|μ|p>=∫odd·odd·odd dr=0.

In the direct semiconductor, the gap is made minimum at the Γ point so as to satisfy the selection rule of the wave number. In the direct semiconductor, the wave functions of the conduction band and the valence band are expressed by the s-orbital and the p-orbital, respectively, with the result that the selection rule of the symmetry is also satisfied.

On the other hand, in the indirect semiconductor, the conduction band and the valence band differ from each other in the wave number making the gap minimum, resulting in failure to satisfy the selection rule of the wave number. In addition, since the wave functions for both conduction band and valence band are represented by the p-orbital, the selection rule of the symmetry is not satisfied either. It follows that the indirect semiconductor is optically forbidden.

(3) FT Semiconductor:

The FT semiconductor is a theoretic material that was discovered in 1984 in the process of calculating the conduction band structure of GaAs (see H. W. A. M. Rompa et al., Phys. Rev. Lett., 52, 675 [1984] and D. M. Wood et al., Phys. Review B31, 2570 [1985]). Rompa et al., who discovered the theoretic substance, found through the band calculation that FT-GaAs having He introduced into the interstitial sites of GaAs exhibits an increase in X point energy.

The present invention uses the FT semiconductor as a new band engineering method and applies the FT semiconductor structure, which allows the X point energy to be controlled, to an indirect semiconductor such as silicon. This imparts a significant light absorption to the indirect semiconductor, which originally exhibits only an insignificant light absorption.

As described above, the term “FT semiconductor” conventionally refers to a crystalline solid in which a rare gas atom or a diatomic molecule with an electron configuration of a closed shell is introduced into an “interstitial site” of a matrix semiconductor having a tetrahedral structure such as a diamond structure or a zinc blende structure.

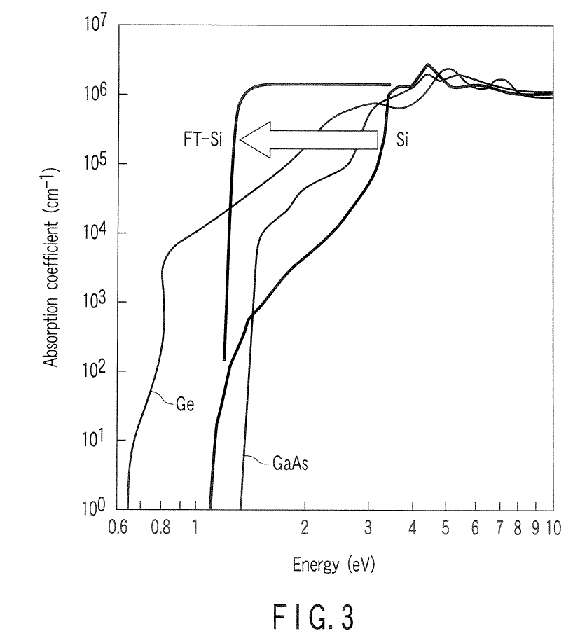

Description will be given of the difference between the band structures of the ordinary crystalline silicon and the FT semiconductor. FIG. 2A is a band diagram of crystalline silicon. FIG. 2B is a band diagram of He-doped FT-silicon. FIG. 2B shows the first principle band calculation in respect of silicon with an FT structure (hereinafter referred to as FT-silicon), in which a He atom is imaginarily inserted in the interstitial site of crystalline silicon. As apparent from these diagrams, the band structure of the FT-silicon is modulated into a direct transition type well resembling that of GaAs in which the shape of the conduction band is widely varied from that of the crystalline silicon. One of effects of the FT semiconductor is to significantly modulate the indirect band structure of the indirect semiconductor, exemplified by silicon, into a direct one to sharply increase an absorption coefficient for a part of absorption spectrum of silicon from the band edge toward a high energy side as shown in FIG. 3.

(4) Principle of Enhancement of Absorption in the FT Semiconductor:

FIGS. 4A, 4B, and 4C are show electron states in the real space in respect of the Γ point conduction band (Γc), the X point conduction band (Xc), and the Γ point valence band (Γv), respectively, in the energy band of silicon.

As shown in FIG. 4A, silicon atoms are positioned at the atomic coordinates (0, 0, 0) and (1/4, 1/4, 1/4) as viewed in the direction of the crystal axis <111> and bonded to each other by the Si—Si bond. Interstitial sites called tetrahedral sites are arranged at the atomic coordinates (2/4, 2/4, 2/4) and (3/4, 3/4, 3/4). The tetrahedral structure has a crystal structure having a relatively large clearance in which two atoms, two interstitial sites, and again two atoms are arranged along the crystal axis <111>. No atom is present in the interstitial site. However, since the anti-bonding and bonding p-orbitals of the silicon atom are expanded toward the interstitial site, an electron state is present in the interstitial site. In short, the state of the p-orbital is present in the interstitial site. The principle of enhancement of absorption is based on the formation of an FT structure in the interstitial site with resultant selective modulation of the p-orbital.

In the well-known FT semiconductor, the FT structure is formed by introducing a rare gas atom (or molecule) with an electron configuration of a closed shell into the space in the interstitial site. The FT structure formed excludes an electron from the interstitial site to increase the energy of Xc and Γv attributed to the p-orbital. However, the Γc energy attributed to the anti-bonding s-orbital is almost unaffected. This reduces, therefore, the difference between the Γc energy and the Γv energy to lower the level of Γc relative to Γv, resulting in a direct transition. This increases the light absorption.

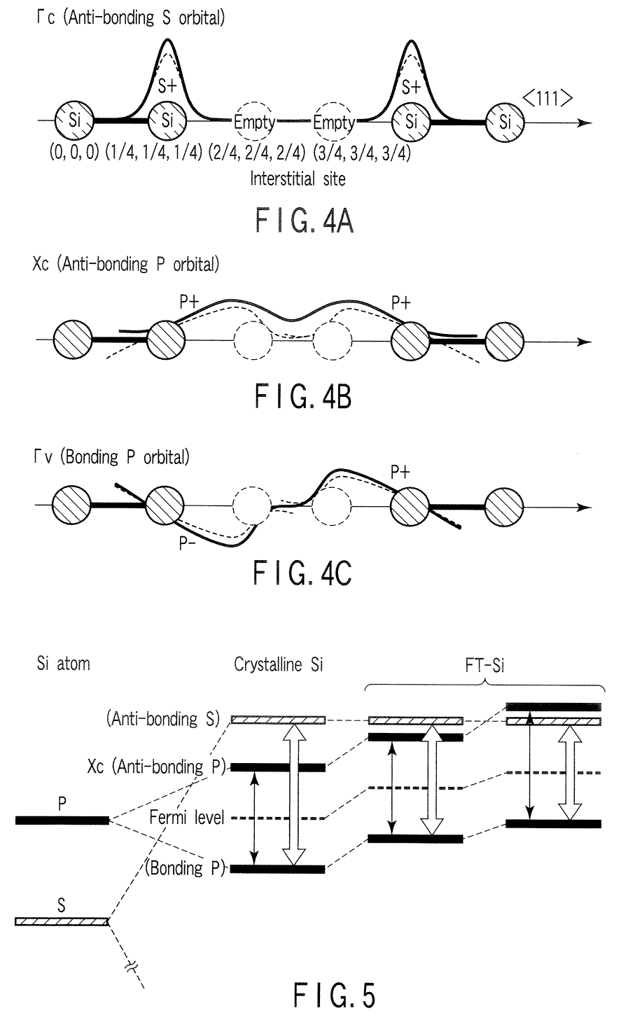

The above discussions will be summarized with reference to an energy band diagram shown in FIG. 5. As shown in this diagram, in the crystalline silicon, the p-orbitals constitute the bottom of the conduction band and the top of the valence band. The s-orbital is positioned upward in the conduction band. The formation of the FT structure involves introducing the rare gas atom (or molecule) into the interstitial site to raise the two p-orbitals closer to the s-orbital and further to cause level crossing. An optically allowed s-p transition exhibiting significant absorption is shifted toward a low energy side to improve the absorption coefficient in a long wavelength region.

The presence of an atom in the interstitial site may form a deep or defect level within the band gap, which may reduce a light current. However, in the FT structure, the atom (or molecule) of the closed shell structure having a wide gap is inserted into the interstitial site, which prevents in principle the formation of such a level.

(5) Problems with the Rare Gas-Containing or Molecule-Containing FT Semiconductor:

However, the rare gas-containing or molecule-containing FT semiconductor proposed by Rompa et al. is believed to be thermally unstable because the inserted substance can move within the crystal and, thus, not to be suitable for practical use.

Concerning the FT semiconductor, the result of an experiment is reported that, if rare gas atoms are ion-implanted in a silicon wafer, photoluminescence (PL emission) is generated in the energy region in the vicinity of 1 eV, though the mechanism of the PL emission is not clarified (see N. Burger et al., Phys. Rev. Lett., 52, 1645 [1984]). However, if the wafer in which the rare gas atoms have been ion-implanted is annealed, the PL emission is caused to disappear, though the reason therefore is again not clear. It is believed that the disappearance of PL emission is derived from the fact that, since the rare gas atom is not chemically bonded with the silicon atom, the rare gas atom is diffused within the silicon crystal and may be finally released from the wafer.

Accordingly, even if the rare gas-containing or molecule-containing FT semiconductor can be formed into the FT structure, the resultant structure is easily expected to be poor in thermal stability. In short, there is a problem that the conventional FT semiconductor will not be a practical material system.

(6) Novel Pendant Type FT Semiconductor:

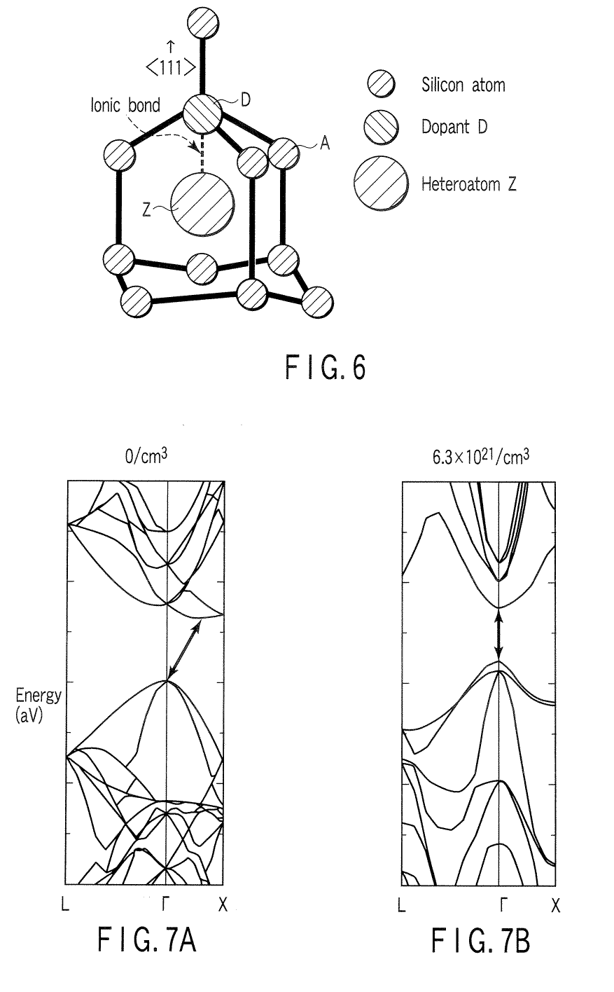

FIG. 6 shows a bonding state of atoms in a novel FT semiconductor according to an embodiment. The novel FT semiconductor is referred to as a pendant type FT semiconductor. The pendant type FT semiconductor, constituting the important part of the present invention, comprises silicon atoms of a matrix semiconductor having a tetrahedral structure, an n-type dopant D (or p-type dopant A) substituted for a silicon atom in a lattice site, and a heteroatom Z inserted into an interstitial site positioned closest to the dopant D (or A). The heteroatom Z has an electron configuration of a closed shell structure through charge compensation with the dopant D (or A) and is ionized. Thus, an ionic bond is formed between the dopant D (or A) and the heteroatom Z, allowing the dopant D (or A) to pin the heteroatom Z. The pendant type FT semiconductor of this particular structure permits improving the thermal stability, which is a problem with the rare gas-containing or molecule-containing FT semiconductor. This is because, if the dopant D (or A) and the heteroatom Z are to be pulled away from each other, electrostatic interaction is exerted between them so as to generate force for maintaining the ionic bond.

FIG. 6 shows a pendant type FT semiconductor in which phosphorus (P) as the n-type dopant D and fluorine (F) as the heteroatom Z, inserted into the interstitial site closest to the dopant D, are introduced into silicon atoms forming a matrix semiconductor. The electron configuration of the P atom is 1s²2s²2p⁶3s²3p³, and that of the F atom is 1s²2s²2p⁵. A charge compensation effect is exerted between these two atoms to form an ionic P⁺—F⁻ bond (PF pair). The P⁺ ion is substituted for the silicon atom at the lattice point to change into a tetrahedral structure and is thus stabilized. The F⁻ ion becomes to have an electron configuration of a closed shell structure like neon (Ne) and is thus also stabilized.

Where a pendant type FT semiconductor is to be realized by using silicon, it is possible to use an n- or p-type dopant, which has already been used in the actual LSI process, can be used as it is for the dopant D (or A). This facilitates the manufacture of the pendant type FT semiconductor so as to reduce the manufacturing cost thereof.

For the pendant type FT semiconductor according to the embodiment, whether a light receiving function can be imparted to the indirect semiconductor is important as in the case of the rare gas-containing or molecule-containing FT semiconductor. FIGS. 7A and 7B show the results of band calculations based on the first principle in respect of a PF-doped FT-Si, in which phosphorus (P) is used as the dopant D and fluorine (F) is used as the heteroatom Z. The results cover two cases of FIG. 7A where the number of PF pairs is zero (the PF concentration is zero, and the Si atom concentration is 5.0×10²²/cm³), and FIG. 7B where the number of PF pairs is one relative to seven Si atoms (the PF concentration is 6.3×10²¹/cm³).

According to the results of calculations, in the case where the PF pair concentration is zero shown in FIG. 7A, there is the lowest edge of the conduction band in the vicinity of Xc, which indicates an indirect band structure inherent in crystalline silicon. In the case where the PF pair concentration is 6.3×10²¹/cm³ shown in FIG. 7C, the Xc is markedly raised so as to cause the whole substance to be changed into a direct band structure. These calculations indicate that the introduction of the PF pair changes the inter-band transition itself to be optically allowed, increasing absorption in the whole substance.

In conclusion, the pendant type FT semiconductor, like the rare gas-containing or molecule-containing FT semiconductor, is considered to produce the effect of band-modulating an indirect semiconductor into a direct semiconductor to sharply increase the absorption coefficient of the inter-band transition. The absorption coefficient is expected to increase consistently with the pair concentration.

In the embodiments, combinations of the matrix semiconductor, dopant D or A, and heteroatom Z contained in the pendant type FT semiconductor are exemplified as follows.

(1) The matrix semiconductor is selected from the group consisting of IVb elemental semiconductors and IVb-IVb compound semiconductors, the dopant D is selected from the group consisting of Va elements and Vb elements, and the heteroatom Z is selected from the group consisting of VIIb elements.

(2) The matrix semiconductor is selected from the group consisting of IVb elemental semiconductors and IVb-IVb compound semiconductors, the dopant A is selected from the group consisting of IIIa elements and IIIb elements, and the heteroatom Z is selected from the group consisting of Ia elements and Ib elements.

Combinations of the matrix semiconductor other than the IVb elemental semiconductor, the dopant D or A, and the heteroatom Z are exemplified as follows.

(3) The matrix semiconductor is selected from the group consisting of IIIb-Vb compound semiconductors, the dopant D is selected from the group consisting of IVa elements and IVb elements and substituted for the IIIb atom at a lattice site, and the heteroatom Z is selected from the group consisting of VIIb elements.

(4) The matrix semiconductor is selected from the group consisting of IIIb-Vb compound semiconductors, the dopant A is selected from the group consisting of IIa elements and IIb elements and substituted for the IIIb atom at a lattice site, and the heteroatom Z is selected from the group consisting of Ia elements and Ib elements.

(5) The matrix semiconductor is selected from the group consisting of IIIb-Vb compound semiconductors, the dopant D is selected from the group consisting of VIa elements and VIb elements and substituted for the Vb atom at a lattice site, and the heteroatom Z is selected from the group consisting of VIIb elements.

(6) The matrix semiconductor is selected from the group consisting of IIIb-Vb compound semiconductors, the dopant A is selected from the group consisting of IVa elements and IVb elements and substituted for the Vb atom at a lattice site, and the heteroatom Z is selected from the group consisting of Ia elements and Ib elements.

The matrix semiconductor can be exemplified as follows. An example of the IVb elemental semiconductor includes silicon. The IVb-IVb compound semiconductor is selected from the group consisting of SiC, GeC, SiₓGe₁₋ₓ (0<x<1) and SiₓGe_{y}C_{1-x-y} (0<x<1, 0<y<1, 0<x+y<1). The IIIb-Vb compound semiconductor is selected from the group consisting of BN, BP, AlP, AlAs, AlSb and GaP.

The dopant D or A, and the heteroatom Z can be exemplified as follows. The Ia element is selected from the group consisting of Li, Na, K, Rb and Cs. The IIa element is selected from the group consisting of Be, Mg, Ca, Sr, and Ba. The IIIa element is selected from the group consisting of Sc, Y, La and Lu. The IVa element is selected from the group consisting of Ti, Zr and Hf. The Va element is selected from the group consisting of V, Nb and Ta. The VIa element is selected from the group consisting of Cr, Mo and W. The Ib element is selected from the group consisting of Cu, Ag, and Au. The IIb element is selected from the group consisting of Zn, Cd, and Hg. The IIIb element is selected from the group consisting of B, Al, Ga, In and Tl. The IVb element is selected from the group consisting of C, Si, Ge, Sn and Pb. The Vb element is selected from the group consisting of N, P, As, Sb, and Bi. The VIb element is selected from the group consisting of O, S, Se and Te. The VIIb element is selected from the group consisting of F, Cl, Br and I.

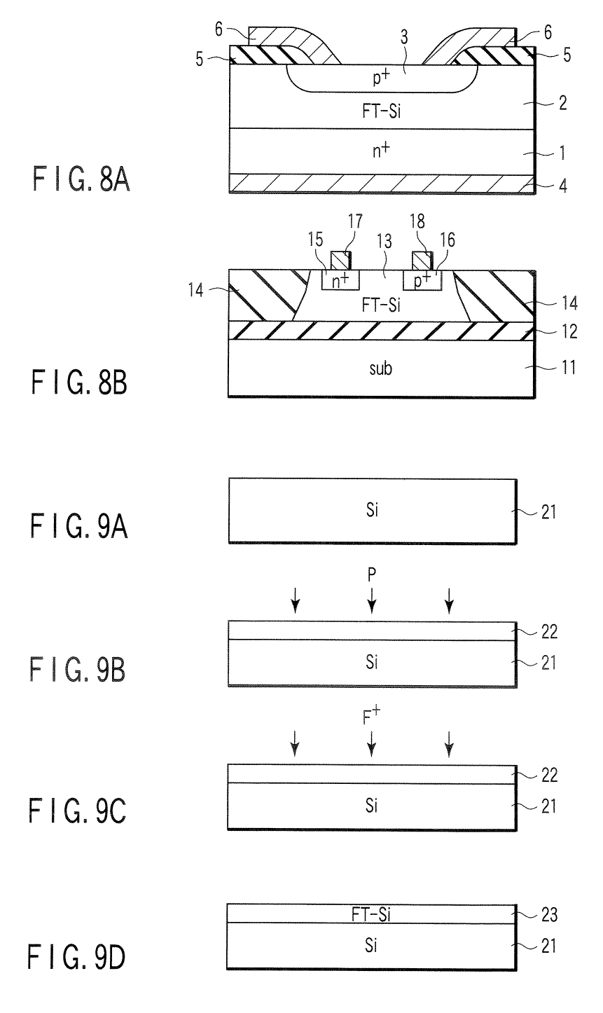

The optical receiving device according to an embodiment has a photocarrier generation layer (photoelectric conversion layer) comprising an FT semiconductor. The positions of electrodes relative to the photoelectric layer are not particularly limited. FIGS. 8A and 8B are cross-sectional views showing the structures of silicon optical receiving devices according to embodiments. FIG. 8A shows a vertical type optical receiving device. FIG. 8B shows a lateral type optical receiving device.

In the optical receiving device of the vertical type shown in FIG. 8A, an photocarrier generation layer 2 comprising FT-Si is formed on an n⁺ region 1, and a p⁺ region 3 is formed in the photocarrier generation layer 2. In other words, the n⁺ region 1 and the p⁺ region 3 are in contact with the photocarrier generation layer 2 so as to interpose the photocarrier generation layer 2 therebetween. An n-electrode 4 is connected to the n⁺ region 1, and a p-electrode 6 is connected to the p⁺ region 3. The photocarrier generation layer 2 and p electrode 6 are insulated with an insulating layer 5.

In this optical receiving device, light carriers (electrons and holes) generated in the photocarrier generation layer are drifted in the vertical direction to obtain electrons from the n electrode 4 via the n⁺ region 1 and to obtain holes from the p electrode 6 via the p⁺ region 3, and thus a light current is produced.

In the optical receiving device of the lateral type shown in FIG. 8B, a buried oxide film 12 is formed in a semi-insulating silicon substrate 11, and a photocarrier generation layer 13 comprising FT-Si is formed on the buried oxide film 12. An insulating film 14 isolates the photocarrier generation layer 13. An n⁺ region 15 and a p⁺ region 16 are formed in a surface area of the photocarrier generation layer 13 so as to sandwich the photocarrier generation layer 13 therebetween in the same plane. An n-electrode 17 is connected to the n⁺ region 15, and a p-electrode 18 is connected to the p⁺ region 16.

In this optical receiving device, light carriers (electrons and holes) generated in the photocarrier generation layer 13 are drifted in the lateral direction to obtain electrons from the n electrode 17 via the n⁺ region 15 and to obtain holes from the p electrode 18 via the p⁺ region 16, and thus a light current is produced.

In both vertical and lateral type optical receiving devices, the buried oxide film is formed for preventing current leakage. However, the buried oxide film need not necessarily be formed if the current leakage can be prevented by any means such as the element structure, substrate resistivity, and circuit.

Each of FIGS. 8A and 8B shows the basic structure of the optical receiving device, and various structures are possible for specific optical receiving devices. For example, the optical receiving device according to the embodiments can be used as a unit element. A plurality of optical receiving devices may be integrated together on the same substrate to produce a CCD image sensor or a CMOS image sensor. A plurality of optical receiving devices may be integrated together on the same substrate to form a solar cell panel. Optical receiving devices, light emitting devices, and waveguides connecting them may be integrated together on the same substrate to produce an optical device array. These modifications will be described below in detail.

A method of forming a photocarrier generation layer having an FT structure will now be described with reference to FIGS. 9A, 9B, 9C and 9D. In the following description, a photocarrier generation layer of PF-doped FT-Si is formed.

A Si wafer 21 is prepared as shown in FIG. 9A. A prescribed doping region 22 of the Si wafer 21 is then doped with phosphorus (P) as an n-type dopant D, as shown in FIG. 9B.

As shown in FIG. 9C, fluorine (F⁺) as a heteroatom Z is ion-implanted into a prescribed doping region 22 of the Si wafer 21 already doped with P. In the ion implantation step, optimization is made of energy, dose, surface orientation of the substrate, tilt angle, substrate temperature, and so forth. The F⁺ ion is expected to receive an excess electron possessed by the P atom and an electron fed from ground through the substrate to become an F⁻ ion.

In the step shown in FIG. 9D, annealing is carried out to recrystallize the lattice disturbed by the ion implantation to form an photocarrier generation layer 23 comprising FT-Si. In the annealing process, the annealing temperature, annealing time, atmosphere, and so forth are adjusted to controllably replace the silicon atom at the lattice point with the P atom and to insert the F atom into the interstitial site. The P atom is positioned at the lattice point. However, the F atom takes the electron from the P atom to make the P atom electrically inactive. P atom thus provides an increased resistivity. The P atom and the F atom are tonically bonded together and are not dissociated from each other in spite of a temperature rise during the annealing. The p and F atoms thus maintain a paired state.

Further, the other steps are carried out to enable the production of such an optical receiving device as shown in FIG. 8A or 8B.

As described above, a photocarrier generation layer having an FT structure can be formed in a matrix semiconductor by the method employing the combination of ion implantation and annealing. Alternatively, a photocarrier generation layer having an FT structure can be formed by a combination of thermal diffusion and annealing. A photocarrier generation layer having an FT structure can also be formed by any other method.

If the dopant D at the lattice point is bonded to the heteroatom Z in the interstitial site as in the case of the PF pair, an inherent vibration mode differing from the lattice vibration of the matrix semiconductor is generated. As a result, it is possible to analyze directly the FT structure by infrared spectroscopy or Raman spectroscopy. When it comes to an example of the PF pair, the calculation of the standard vibration indicates that a vibration mode appears in the vicinity of the wave number of 150 to 200 cm⁻¹. In this fashion, evaluation of the vibration mode provides one of effective means of examining the presence of the FT structure.

As an indirect and simple method of detecting the presence of a DZ (or AZ) pair, it is possible to employ an electrical measurement such as resistance measurement or Hall measurement. In the case of using an n-type (or p-type) dopant, the substrate before doping the heteroatom Z in the interstitial site exhibits n-type or p-type conductivity and, thus, has a low resistivity. If the dopant D (or A) is paired with the heteroatom Z, charge compensation reduces free carriers to increase the resistivity of the substrate. Thus, it is possible to detect whether the DZ (or AZ) pair has been formed by comparing the resistances or the carrier concentrations before and after the doping of the heteroatom Z.

The present invention will be described in more detail with reference to specific embodiments.

### First Embodiment

A silicon optical receiving device of the lateral type, which is constructed as shown in FIG. 8B, will be described. A PF doped FT-Si photocarrier generation layer is formed by using silicon as the matrix semiconductor, the P atom as an n-type dopant D substituted for a lattice site, and the F atom as a heteroatom Z inserted into an interstitial site. The PF pair concentration is set to 5×10²¹/cm³. The concentrations of the P atoms and the F atoms are determined by secondary ion mass spectroscopy (SIMS).

To determine whether a PF pair of a pendant type FT structure is formed in the photocarrier generation layer 13, it is effective to examine the vibration mode inherent in the PF pair, which can be detected by microspectroscopy of the photocarrier generation layer. A method for easily checking the PF pair formation is to form a PF-doped region having the same composition as that of the photocarrier generation layer and a region doped only with P on the surface of a high-resistivity substrate and then to compare these two doped regions for sheet resistance or carrier concentration. The formation of a PF pair leads to charge compensation to increase the resistivity of the PF-doped region above that of the region doped only with P, while reducing the carrier concentration of the PF-doped region below that of the region doped only with P.

As seen from the result of the band calculation in FIG. 7, the band gap of the PF-doped FT-Si is substantially equal to that of the crystalline silicon. When the optical receiving device is irradiated with light with energy equal to or greater than the band gap to optically excite the PF-doped FT-Si in the photocarrier generation layer, a light current is generated.

To effectively derive the light current which has been generated in the photocarrier generation layer via the electrodes, a driving voltage V is applied to between the n electrode 17 and the p electrode 18 (not shown in FIG. 8B). Supposing the open circuit voltage between the electrodes of the optical receiving device is V_{OC}, a driving voltage should meet the following formula: V<V_{OC}. In contrast, in a case where V>V_{OC}, external carriers from the electrode are injected into the photocarrier generation layer to cancel and decrease the light current. Thus, the setting of the operating voltage V is an important factor determining the device characteristics. The open circuit voltage V_{OC} can be determined by scanning the driving voltage so as to zero the light current (V=V_{OC}).

FIG. 10 shows the response characteristics of output light currents observed when optical signals with a wavelength of 850 nm modulated at 10 GHz are input to the optical receiving device according to the embodiment. As is apparent from FIG. 10, output light currents having the same waveform are obtained in response to the input optical signals. Thus, the optical receiving device according to the embodiment enables the high-speed detection of near infrared light with the wavelength of 850 nm, for which the crystalline silicon exhibits low spectral sensitivity.

As described above, the pendant type FT semiconductor modulating the energy band is very effective for imparting a high light absorbing function to the photocarrier generation layer of the silicon-based optical receiving device to increase the operating speed and sensitivity of the optical receiving device.

### COMPARATIVE EXAMPLE

A device is produced which has exactly the same configuration as that of the device according to the first embodiment except that the B atom is used as the heteroatom Z in place of the F atom. The B concentration is set to 5×10²¹/cm³, which is equal to the F concentration in the first embodiment.

Optical signals with a wavelength of 850 nm modulated at 10 MHz are input to this optical receiving device to examine the output currents. The optical receiving device in the comparative example provides only low output currents and fails to sense the optical signals.

The insufficient output currents are due to the position of the B atom in the crystal. As widely known in the art, the B atom is a typical p-type dopant and is substituted for the lattice site, not the interstitial site. Thus, the charge compensation between the B atom and the P atom increases the resistivity of the photocarrier generation layer. However, the pendant type FT structure is not formed.

Therefore, in order to induce a high light absorbing function by forming a pendant type FT structure to modulate the band structure, sufficient consideration must be given in selecting the combination of the dopant substituted for the lattice site and the heteroatom inserted into the interstitial site.

### Second Embodiment

An optical receiving device having exactly the same configuration as that in the first embodiment is produced except that the B atom, a p-type dopant, is used as the dopant D and the K atom is used as the heteroatom Z. The B concentration and K concentration as determined by SIMS are both 4×10²¹/cm³, and the BK pair concentration is estimated at 4×10²¹/cm³.

To determine whether a BK pair of the pendant type FT structure is formed in the photocarrier generation layer, it is effective to determine the vibration mode inherent in the BK pair. It can also be determined by using a simpler method based of the resistivity value or carrier concentration.

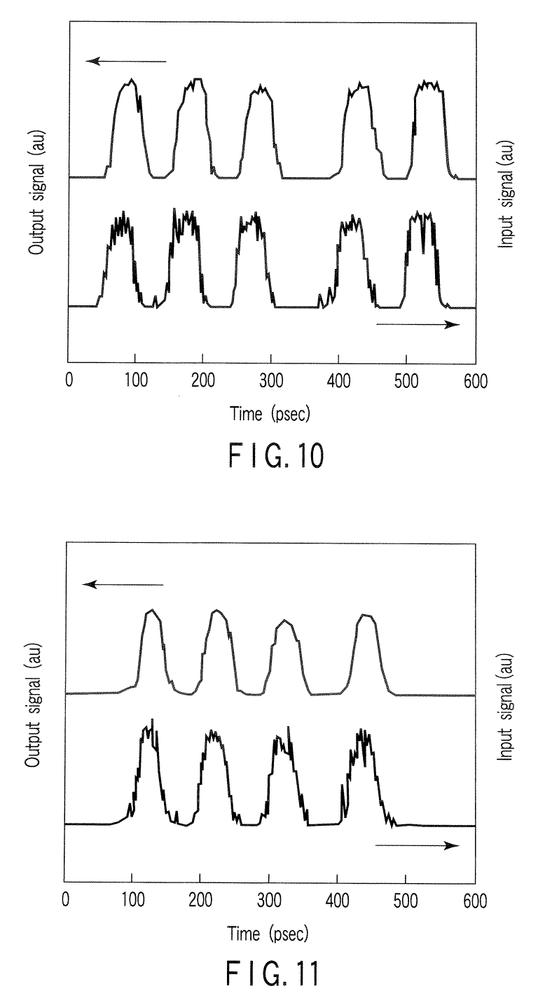

FIG. 11 shows the response characteristics of output light currents observed when optical signals with a wavelength of 850 nm modulated at 10 GHz are input to the optical receiving device according to the embodiment. As is apparent from FIG. 11, output light currents having the same waveform are obtained in response to the input optical signals.

As seen from the embodiment, even with the combination of the p-type dopant and the heteroatom Z, the operating speed and sensitivity of the optical receiving device can be increased by forming a pendant type FT structure in the photocarrier generation layer to enhance light absorption.

### Third Embodiment

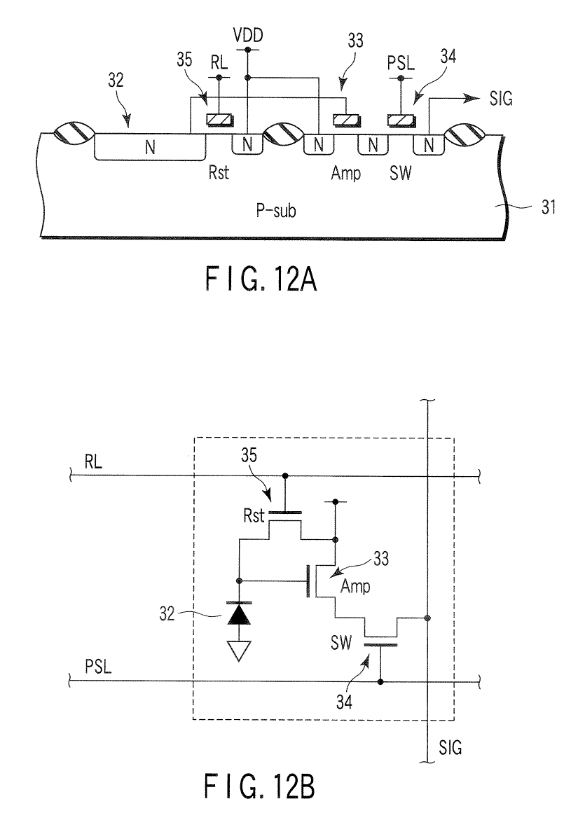

FIGS. 12A and 12B show a CMOS image sensor according to a third embodiment. FIG. 12A is a cross-sectional view, and FIG. 12B is a circuit diagram. The CMOS image sensor comprises pixel circuits (the circuit is depicted in a region enclosed by a dashed line in FIG. 12B) integrated on the same p-type Si substrate 31. Each pixel circuit includes a photocarrier generation layer 32 comprising an n-type region, an amplifying element 33 that amplifies optical outputs from the photocarrier generation layer 32, a select transistor 34 that selects the pixels, and a reset transistor 35 that resets signal charges. The photocarrier generation layer 32 has basically the same structure as that of the photocarrier generation layer shown in the first embodiment. The amplifying element 33, select transistor 34, and reset transistor 35 are all MOS transistors. The select transistor 34 has a gate electrode connected to a perpendicular select line PSL and a drain connected to a signal line SIG. The reset transistor 35 has a gate electrode connected to a reset line RL.

When optical signals containing red light and near infrared light with a wavelength greater than 600 nm are selectively input to the CMOS image sensor via a filter, well contrasted output images (electrical signals) are provided.

Thus, the CMOS image sensor according to the embodiment enables sensitive image pickup even with light having a wavelength greater than 600 nm, for which the crystalline silicon exhibits only low spectral sensitivity.

### Fourth Embodiment

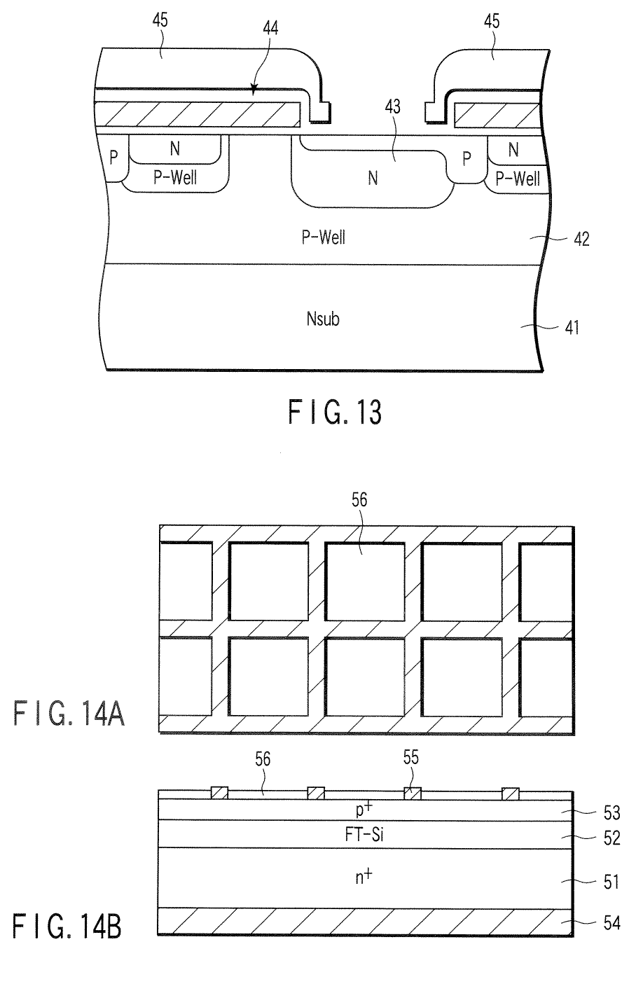

FIG. 13 is a cross-sectional view of a pixel circuit in a CCD image sensor according to a fourth embodiment. In the CCD image sensor, pixel circuits are integrated on the same substrate. In FIG. 13, a p well 42 is formed on an n-type Si substrate 41, and an n-type photocarrier generation layer 43 is formed in the p well 42. The photocarrier generation layer 43 has basically the same structure as that of the photocarrier generation layer shown in the first embodiment. The n-type region 43 is connected to a read transistor 44. Light is input to the n-type region 43 to generate signal charges, which are then read, via the read transistor 44, onto a vertical CCD comprising a transfer electrode. A light shielding film 45 is formed on the read transistor 44 with an insulating layer interposed.

When optical signals with a wavelength greater than 600 nm are selectively input to the CMOS image sensor through a filter, well contrasted output images (electrical signals) are provided.

Thus, the CCD image sensor according to the embodiment enables sensitive image pickup even with light having a wavelength greater than 600 nm, for which the crystalline silicon exhibits only low spectral sensitivity.

### Fifth Embodiment

FIG. 14A and FIG. 14B show the cell structure of a solar cell according to this embodiment. FIG. 14A is a plan view, and FIG. 14B is a cross-sectional view. The solar cell comprises optical receiving devices (cells) integrated on the same substrate.

In the solar cell, an n⁺ layer 51, a photocarrier generation layer 52 comprising FT-Si, and a p⁺ layer 53 are stacked. A back electrode 54 is formed on a back surface of the n⁺ layer 51. Lattice-shaped surface electrodes 55 are formed on the surface of the p⁺ layer 53. Antireflection coatings 56 are formed in the areas surrounded by the surface electrodes 55.

When the solar cell is irradiated with false sunlight to determine conversion efficiency, it is found to be 50%. This value is higher than the efficiency of a solar cell comprising crystalline silicon (20 to 30%) or an amorphous silicon (10 to 15%).

Thus, the solar cell according to the embodiment can effectively absorb sunlight using the photocarrier generation layer with a high absorption coefficient, achieving a high conversion efficiency.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An optical receiving device, comprising:
a photoelectric conversion layer comprising a matrix semiconductor containing silicon atoms as a main component, an n-type dopant D substituted for the silicon atom in a lattice site, and a heteroatom Z inserted into an interstitial site positioned closest to the n-type dopant D,
the heteroatom Z having an electron configuration of a closed shell structure through charge compensation with the dopant D.

2. The device according to claim 1, wherein the n-type dopant D is selected from Vb elements and the heteroatom Z is selected from VIIb elements.

3. The device according to claim 2, wherein the Vb element is P atom and the VIIb element is F atom.

4. The device according to claim 1, further comprising a pair of electrodes between which the photoelectric conversion layer is disposed.

5. The device according to claim 4, wherein supposing an open circuit voltage between the electrodes is V_{OC}, a driving voltage V meets the following formula: V<V_{OC}.

6. A CCD image sensor comprising:
the photoelectric conversion layer according to claim 1; and
a transfer electrode adjacent to the photoelectric conversion layer,
the photoelectric conversion layer and the transfer electrode being formed on a same substrate.

7. A CMOS image sensor comprising:
the photoelectric conversion layer according to claim 1; and
an amplifying element connected to the photoelectric conversion layer via a wire,
the photoelectric conversion layer and the amplifying element being formed on a same substrate.

8. A solar cell comprising:
a plurality of the optical receiving devices according to claim 1 formed on a same substrate.

9. An optical receiving device comprising:
a photoelectric conversion layer comprising a matrix semiconductor containing silicon atoms as a main component, a p-type dopant A substituted for the silicon atom in a lattice site, and a heteroatom Z inserted into an interstitial site positioned closest to the p-type dopant A,
the heteroatom Z having an electron configuration of a closed shell structure through charge compensation with the dopant A.

10. The device according to claim 9, wherein the p-type dopant A is selected from IIIb elements and the heteroatom Z is selected from Ia elements.

11. The device according to claim 10, wherein the IIIb element is B atom and the Ia element is K atom.

12. The device according to claim 9, further comprising a pair of electrodes between which the photoelectric conversion layer is disposed.

13. The device according to claim 12, wherein supposing an open circuit voltage between the electrodes is V_{OC}, a driving voltage V meets the following formula: V<V_{OC}.

14. A CCD image sensor comprising:
the photoelectric conversion layer according to claim 9; and
a transfer electrode adjacent to the photoelectric conversion layer,
the photoelectric conversion layer and the transfer electrode being formed on a same substrate.

15. A CMOS image sensor comprising:
the photoelectric conversion layer according to claim 9; and
an amplifying element connected to the photoelectric conversion layer via a wire,
the photoelectric conversion layer and the amplifying element being formed on a same substrate.

16. A solar cell comprising:
a plurality of the optical receiving devices according to claim 9 formed on a same substrate.
